(19) United States
(12) Patent Application Publication
(10) Pub. No.: US 2022/0320096 A1
(43) Pub. Date: Oct. 6, 2022

(54) CAPACITOR ARRAY STRUCTURE AND PREPARATION METHOD THEREOF AND SEMICONDUCTOR MEMORY DEVICE

(71) Applicant: CHANGXIN MEMORY TECHNOLOGIES, INC., Hefei, Anhui (CN)

(72) Inventor: Liang ZHAO, Hefei (CN)

(73) Assignee: CHANGXIN MEMORY TECHNOLOGIES, INC., Hefei, Anhui (CN)

(21) Appl. No.: 17/310,799

(22) PCT Filed: Mar. 15, 2021
(86) PCT No.: PCT/CN2021/080792

§ 371 Date: Aug. 24, 2021

(30) Foreign Application Priority Data
Apr. 9, 2020 (CN) 202010274575.8

(51) Int. Cl. H01L 27/108

(52) U.S. Cl. CPC H01L 27/1085; H01L 27/10805

(57) ABSTRACT

A preparation method of a capacitor array structure includes: providing a capacitor substrate which comprises an upper electrode filling layer; forming an insulating layer on a side face of the upper electrode filling layer; forming an upper electrode metal layer on an upper surface of the upper electrode filling layer; forming a planarization layer on an outer surface of the upper electrode metal layer; and forming a first conductor which is connected to the upper electrode metal layer after running through the planarization layer as well as a second conductor which is connected to a lower circuit after running through the planarization layer, the insulating layer and an isolation layer.

### CROSS-REFERENCE TO RELATED APPLICATIONS

The present disclosure claims priority to Chinese Patent Application No. 202010274575.8 filed on Apr. 9, 2020, entitled “Capacitor Array structure and Preparation Method Thereof and Semiconductor Memory Device”, which is incorporated herein by reference in its entirety.

### TECHNICAL FIELD

The present disclosure relates to the technical field of semiconductors, in particular to a capacitor array structure and a preparation method thereof, and a semiconductor memory device having the capacitor array structure.

### BACKGROUND

An electrode on a stacked double-sided capacitor of a dynamic random-access memory is generally made of metal (TiN) and a conductive filling material. As shown in FIG. 10, a conductor is generally in contact with the conductive filling material, resulting in a high resistance between the conductor and an upper electrode plate due to the performance of the conductive filling material, which affects the operation efficiency.

### SUMMARY

An objective of the present disclosure is to provide a capacitor array structure, which can reduce the capacitor resistance between a conductor and an upper electrode plate and improve the operation efficiency, as well as a preparation method thereof.

As described in the background, an electrode of a capacitor as shown in FIG. 10 in the related technologies is made of metal and a conductive filling material, and the conductor is generally in contact with a conductive filling layer (an upper electrode filling layer), resulting in a high resistance between the conductor and the upper electrode plate, which affects the operation efficiency.

It is found through research that the resistance between the conductor and the upper electrode plate can be reduced by adding a metal filling layer in the capacitor array structure and making the conductor structure in contact with the metal filling layer. However, as shown in FIG. 9, a metal layer is usually deposited on an outer surface of the upper electrode filling layer in the process of adding a metal filling layer, which inevitably forms upper electrode metal layers on both the top and the side of the upper electrode filling layer. Due to the formation of the metal layer on the side of a capacitor region, a sidewall of the capacitor is thickened and the size of the capacitor array structure is easily enlarged, which is not conducive to improving device integration. Moreover, when the metal layer is deposited on the side of the upper electrode filling layer, the metal layer on the side is also prone to fracture in the later grinding process.

Furthermore, a pin where the sidewall is closest to a second conductor will be formed at the sidewall of the capacitor. As a leakage path between metals is larger than that between the metal and the upper electrode filling layer (after the metal layer is deposited, the etched metal tends to form metal by-products left on an isolation layer, and the metal by-products are left on the isolation layer between the second conductor and an upper electrode in the subsequent formation of the second conductor, resulting in leakage at the bottom of the upper electrode and the second conductor), the leakage defect will be higher when there is a metal layer on the side than in a structure without a metal layer on the sidewall.

In view of this, the present disclosure provides a preparation method of a capacitor array structure, comprising: providing a capacitor substrate, the capacitor substrate comprises an isolation layer, a lower electrode layer, capacitor dielectric layers, an upper electrode layer and an upper electrode filling layer, wherein the isolation layer is disposed on the substrate, the lower electrode layer is disposed above the isolation layer, the capacitor dielectric layers are disposed on inner and outer surfaces of the lower electrode, and the upper electrode layer is disposed on an outer surface of the capacitor dielectric layer and is filled and covered by the upper electrode filling layer; forming an insulating layer on a side face of the upper electrode filling layer; forming an upper electrode metal layer on an upper surface of the upper electrode filling layer; forming a planarization layer on an outer surface of the upper electrode metal layer; and forming a first conductor and forming a second conductor, the first conductor is connected to the upper electrode metal layer after running through the planarization layer, the second conductor is connected to a lower circuit after running through the planarization layer, the insulating layer and the isolation layer.

In this way, by providing the upper electrode metal layer on the top of the upper electrode filling layer and connecting the first conductor to the upper electrode metal layer, it is not only possible to reduce the resistance between the conductor and the upper electrode plate and improve the operation efficiency, but also to make a capacitor array region smaller in size since no upper electrode metal layer is formed on the side face of the upper electrode filling layer, thus making the capacitor array structure smaller in size, improving the device integration, and reducing the risk of leakage at the second conductor and a capacitor pin.

Optionally, forming an insulating layer on a side face of the upper electrode filling layer comprises: forming an insulating layer on an outer surface of the upper electrode filling layer; and removing the insulating layer on the upper surface of the upper electrode filling layer.

Optionally, coating and etching processes are adopted in removing the insulating layer on the upper surface of the upper electrode filling layer.

According to some embodiments of the present disclosure, forming an upper electrode metal layer on an upper surface of the upper electrode filling layer comprises: depositing a metal layer on the upper surface of the upper electrode filling layer and on an upper surface of the insulating layer; and removing the metal layer on the upper surface of the insulating layer and retaining the metal layer on the upper surface of the upper electrode filling layer to form the upper electrode metal layer.

According to some embodiments of the present disclosure, in providing the capacitor substrate, the capacitor substrate is further configured to comprise a plurality of capacitor contact openings, the plurality of the capacitor contact openings are arranged at intervals, plurality of the capacitor contact openings are formed below the isolation layer and connected to the lower electrode layer after running through the isolation layer.

According to some embodiments of the present disclosure, the forming a first conductor and forming a second conductor, the first conductor is connected to the upper electrode metal layer after running through the planarization layer, the second conductor is connected to a lower circuit after running through the planarization layer, the insulating layer and the isolation layer comprises: forming a first through hole in the planarization layer to expose the upper electrode metal layer, filling the first through hole to form the first conductor, forming a second through hole running through the planarization layer, the insulating layer and the isolation layer, and filling the second through hole to form the second conductor.

The present disclosure further provides a capacitor array structure, the capacitor array structure is disposed on a semiconductor substrate and the capacitor array structure comprises: a capacitor substrate, comprising an isolation layer, a lower electrode layer, capacitor dielectric layers, an upper electrode layer and an upper electrode filling layer, wherein a plurality of capacitor contact openings are disposed below the isolation layer, the lower electrode layer is disposed above the isolation layer and connected to the capacitor contact openings after running through the isolation layer, the capacitor dielectric layers are disposed on inner and outer surfaces of the lower electrode, and the upper electrode layer is formed on an outer surface of the capacitor dielectric layer and is filled and covered by the upper electrode filling layer;

an upper electrode metal layer, covering an upper surface of the upper electrode filling layer; an insulating layer, formed on a side face of the upper electrode filling layer; a planarization layer, formed on an outer surface of the upper electrode metal layer; and a conductor, comprising a first conductor and a second conductor, wherein the first conductor is connected to the upper electrode metal layer after running through the planarization layer, and the second conductor is connected to a lower circuit after running through the planarization layer, the insulating layer and the isolation layer in sequence.

According to some embodiments of the present disclosure, a thickness of upper electrode metal layer is 80-120 nm.

According to some embodiments of the present disclosure, a minimum distance between the second conductor and a top of the upper electrode layer is greater than or equal to 300 nm.

The present disclosure further provides a semiconductor memory device, comprising the capacitor array structure according to the above embodiments.

### BRIEF DESCRIPTION OF THE DRAWINGS

FIGS. 1 to 8 are partial structural sectional views of each step of a preparation method of a capacitor array structure according to an embodiment of the present disclosure;

FIG. 9 is a partial structural sectional view of a capacitor array structure according to another embodiment of the present disclosure;

FIG. 10 is a structural diagram of a capacitor array structure in the prior art;

FIG. 11 is a flowchart of a preparation method of a capacitor array structure according to an embodiment of the present disclosure; and

FIG. 12 is a flowchart of a preparation method of a capacitor array structure according to another embodiment of the present disclosure.

Numeral references of the drawings:

100: capacitor array structure;

1: capacitor substrate; 11: isolation layer; 12: capacitor contact opening; 13: upper electrode layer; 14: lower electrode layer, 15: upper electrode filling layer; 16: upper electrode metal layer; 17: dielectric layer; 18: pin;

2: insulating layer;

3: flat layer;

4: first conductor; 41: second conductor; and

5: reticle.

### DETAILED DESCRIPTION

A capacitor array structure and a preparation method thereof proposed in the present disclosure will be further described in detail with reference to the accompanying drawings by the embodiments.

The present disclosure is obtained by the inventor based on the following knowledge and findings.

As described in the background, an electrode of a capacitor as shown in FIG. 10 in the prior art is made of metal and a conductive filling material, and a conductor is generally in contact with a conductive filling layer (an upper electrode filling layer 15), resulting in a high resistance between the conductor and the upper electrode plate, which affects the operation efficiency.

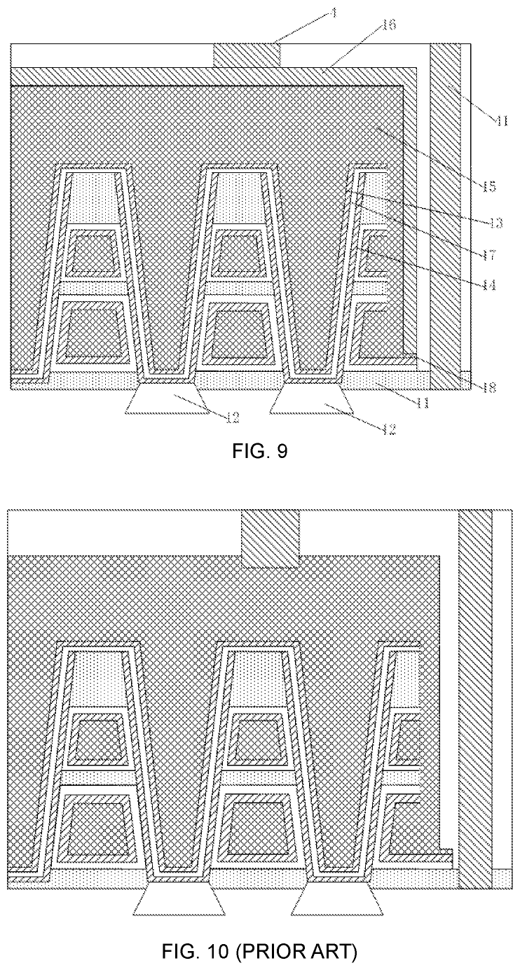

It is found through research that the resistance between the conductor and the upper electrode plate can be reduced by providing an additional metal filling layer in the capacitor array structure and making the conductor structure in contact with the metal filling layer. However, as shown in FIG. 9, a metal layer is usually deposited on an outer surface of the upper electrode filling layer 15 in the process of providing the additional metal filling layer, which inevitably forms upper electrode metal layers on both the top and the side of the upper electrode filling layer 15. Due to the formation of the metal layer on the side of a capacitor region, a sidewall of the capacitor is thickened and the capacitor array structure 100 is easily enlarged, which is not conducive to improving device integration. Moreover, when the metal layer is deposited on the side of the upper electrode filling layer, the metal layer on the side is also prone to fracture in the later grinding process.

Furthermore, a pin 18 at where the sidewall is closest to a second conductor 41 will be formed at the sidewall of the capacitor. As a leakage path between metals is larger than that between the metal and the upper electrode filling layer (after the metal layer is deposited, the etched metal tends to form metal by-products left on an isolation layer 11, and the metal by-products are left on the isolation layer between the second conductor 41 and an upper electrode layer 13 in the subsequent formation of the second conductor 41, resulting in leakage at the bottom of the upper electrode layer 13 and the second conductor), the leakage defect will be higher when there is a metal layer on the sidewall than in a structure without a metal layer on the sidewall.

In view of this, the present disclosure proposes a capacitor array structure 100 and a preparation method thereof to solve the above technical problems.

The capacitor array structure 100 according to an embodiment of the present disclosure will be described below with reference to the accompanying drawings.

As shown in FIG. 8, the capacitor array structure 100 according to the embodiment of the present disclosure may comprise the capacitor array structure 100 disposed on a semiconductor substrate. The capacitor array structure 100 may comprise a capacitor substrate 1, an insulating layer 2, an upper electrode metal layer 16, and conductors.

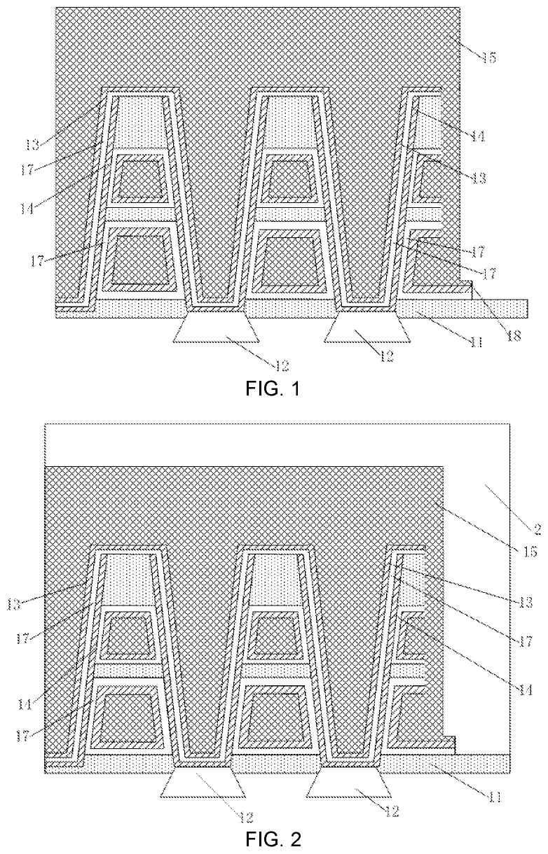

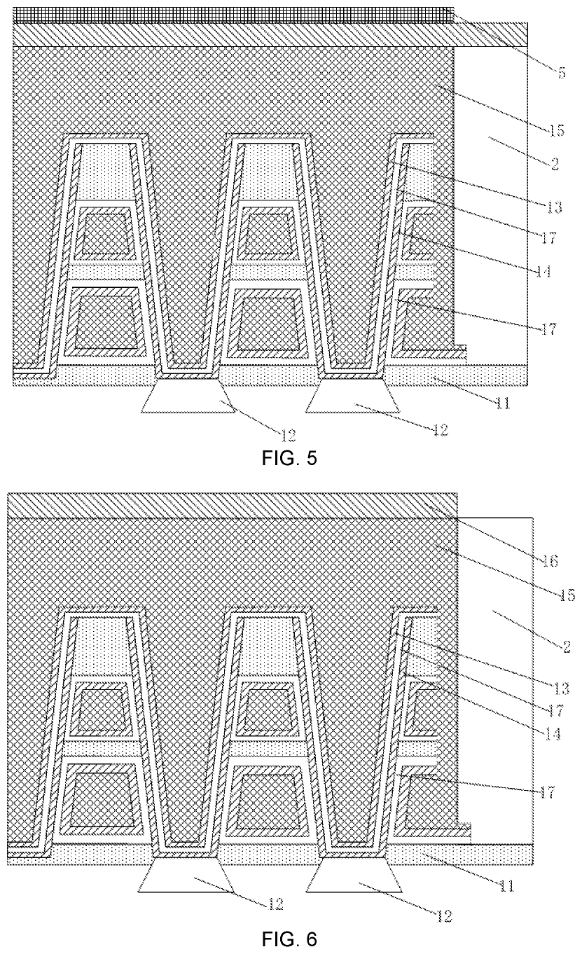

As shown in FIGS. 1 to 8, the capacitor substrate 1 may comprise an isolation layer 11, a lower electrode layer 14, capacitor dielectric layers 17, an upper electrode layer 13 and an upper electrode filling layer 15, wherein a plurality of capacitor contact openings 12 are disposed below the isolation layer 11, and the lower electrode layer 14 is disposed above the isolation layer 11 and connected to the capacitor contact openings 12 after running through the isolation layer 11. Specifically, openings may be formed on the isolation layer 11 to expose the capacitor contact openings 12, the lower electrode layer 14, having the capacitor dielectric layers 17 disposed on inner and outer surfaces thereof, is formed above the isolation layer 11 and the capacitor contact openings 12 and electrically connected to the capacitor contact openings 12, and the upper electrode layer 13 is formed on an outer surface of the capacitor dielectric layer 17 and is filled and covered by the upper electrode filling layer 15. The isolation layer 11 is made of a material comprising but not limited to silicon nitride, the upper electrode layer 13 and the lower electrode layer 14 are made of a material comprising but not limited to titanium nitride, the capacitor dielectric layer 17 is made of a material comprising but not limited to high-k dielectric material, and the upper filling layer is made of a material comprising but not limited to silicon germanium or polysilicon.

The upper electrode metal layer 16 is formed on an upper surface of the upper electrode filling layer 15. As shown in FIG. 8, the upper electrode metal layer 16 is formed only on the upper surface of the upper electrode filling layer 15, with no metal layer formed on a side face of the upper electrode filling layer 15. Optionally, the thickness of the upper electrode metal layer 16 is 80 nm to 120 nm. For example, the thickness of the upper electrode metal layer 16 may be 80 nm, 90 nm, 100 nm or 120 nm, which will not be specifically defined herein and may be determined according to actual conditions and needs. The upper electrode metal layer 16 is made of other materials comprising but not limited to tungsten, copper or aluminum.

An insulating layer 2 is formed on the side face of the upper electrode filling layer 15 and a planarization layer 3 is formed on an outer surface of the upper electrode metal layer 16. Specifically, as shown in FIG. 8, the planarization layer 3 covering an upper surface of the insulating layer 2 is formed on an upper surface and a side face of the upper electrode metal layer 16, wherein the planarization layer 3 and the insulating layer 2 may be made of the same or different materials. In this embodiment, the planarization layer 3 and the insulating layer 2 are made of the same material comprising but not limited to silicon oxide. During the formation of the planarization layer 3 and the insulating layer 2, the insulating layer 2 may be formed on the outer surface of the upper electrode filling layer 15 to avoid the deposition of a metal layer on the side face of the upper electrode filling layer 15, the insulating layer 2 on the upper surface of the upper electrode filling layer 15 is removed, the upper electrode metal layer 16 is formed on the upper surface of the upper electrode filling layer 15, and then the planarization layer 3 is formed on the outer surface of upper electrode metal layer 16.

The conductors comprise a first conductor 4 and a second conductor 41. As shown in FIG. 8, the first conductor 4 is connected to the upper electrode metal layer 16 after running through the planarization layer 3 on the upper surface of the upper electrode metal layer 16, and the second conductor 41 is formed in the insulating layer 2 on the side face of the upper electrode filling layer 15 and connected to a lower circuit after running through the planarization layer 3, the insulating layer 2 and the isolation layer 11 in sequence. It should be noted that the lower circuit here refers to a circuit connected to bit lines, word lines, or circuits in a peripheral region. In this way, the second conductor 41 may be connected to conductors in the peripheral region or bit lines and word lines in an array region of the capacitor array structure 100. As shown in FIG. 8, a minimum distance H between the second conductor 41 and the top of the upper electrode layer 13 is greater than or equal to 300 nm. In this way, by providing the upper electrode metal layer 16 on the upper surface of the upper electrode filling layer 15 and connecting the first conductor 4 to the upper electrode metal layer 16, it is not only possible to reduce the resistance between the conductor and the upper electrode plate and improve the operation efficiency, but also to make a capacitor array region smaller in size since no upper electrode metal layer 16 is formed on the side face of the upper electrode filling layer 15, thus making the capacitor array structure 100 smaller in size, improving the device integration of the capacitor array structure 100, and further reducing the electrode resistance as well as the risk of leakage at the second conductor 41 and a capacitor pin 18.

A preparation method of the capacitor array structure 100 according to an embodiment of the present disclosure will be described below with reference to the accompanying drawings.

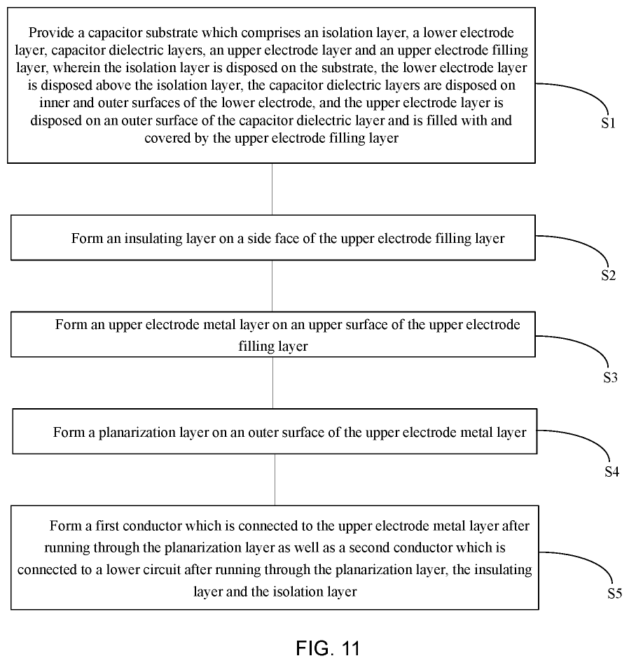

As shown in FIG. 11, the preparation method of the capacitor array structure 100 according to the embodiment of the present disclosure may comprise following steps of: S1, providing a capacitor substrate 1; S2, forming an insulating layer 2 on a side face of an upper electrode filling layer 15; S3, forming an upper electrode metal layer 16 on an upper surface of the upper electrode filling layer 15; S4, forming a planarization layer 3 on an outer surface of the upper electrode metal layer 16; and S5, forming a first conductor 4 which is connected to the upper electrode metal layer 16 after running through the planarization layer 3 as well as a second conductor 41 which is connected to a lower circuit after running through the planarization layer 3, the insulating layer 2 and the isolation layer 11.

Specifically, in the step of providing a capacitor substrate 1 as shown in FIGS. 1 to 8, the capacitor substrate 1 comprises an isolation layer 11, a lower electrode layer 14, capacitor dielectric layers 17, an upper electrode layer 13 and an upper electrode filling layer 15, wherein the isolation layer 11 is disposed on the substrate, the lower electrode layer 14, having the capacitor dielectric layers disposed on inner and outer surfaces thereof, is disposed above the isolation layer 11, and the upper electrode layer 13 is formed on an outer surface of the capacitor dielectric layer 17 and is filled and covered by the upper electrode filling layer 15. As shown in FIG. 1, a capacitor array region is formed on the capacitor substrate 1, and the lower electrode layer 14, the capacitor dielectric layers 17, the upper electrode layer 13 and the upper electrode filling layer 15 are all formed above the isolation layer 11. The capacitor dielectric layer 17 is formed between the upper electrode layer 13 and the lower electrode layer 14, and the upper electrode layers 13 is filled with the upper electrode filling layer 15 and fully covered by the upper electrode layer 13.

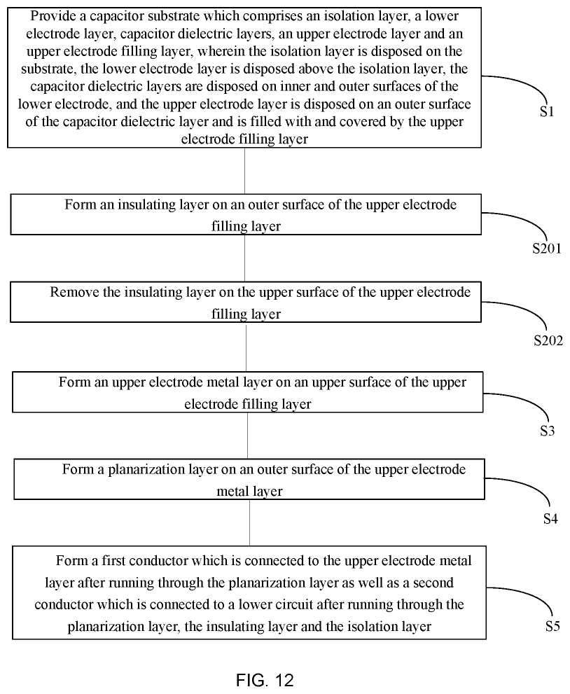

As shown in FIGS. 2, 3 and 12, the step S2 of forming an insulating layer 2 on a side face of the upper electrode filling layer 15 may comprise: S201, forming an insulating layer 2 on an outer surface of the upper electrode filling layer 15; and S202, removing the insulating layer 2 on the top of the upper electrode filling layer 15. As shown in FIG. 2, the insulating layer 2 may be formed on the upper surface and the side face of the upper electrode filling layer 15 in the step S201. In terms of the forming methods of the insulating layer 2, the insulating layer 2 may be deposited and formed on the upper surface and the side face of the upper electrode filling layer 15 by a deposition process.

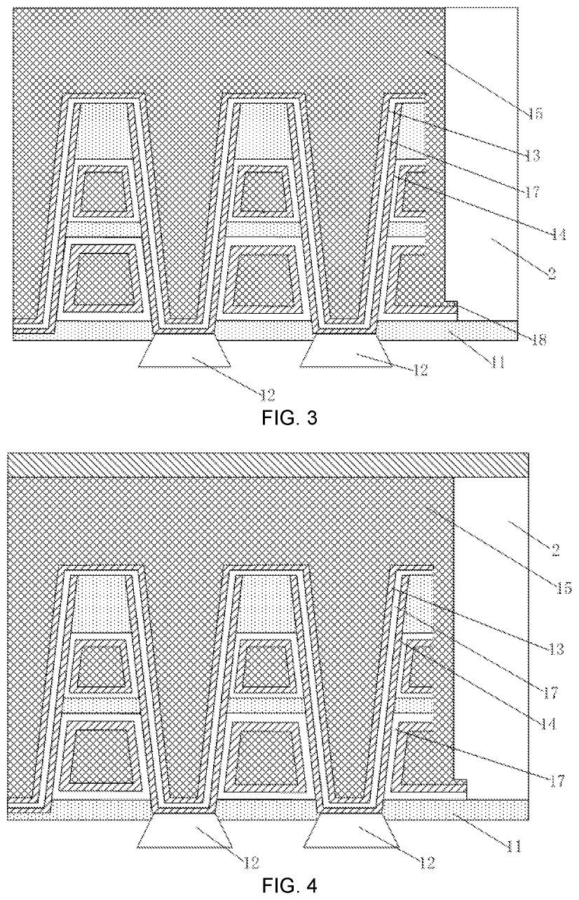

As shown in FIG. 3, the insulating layer 2 on the upper surface of the upper electrode filling layer 15 is removed in the step S202. Specifically, the insulating layer 2 protruded from the upper surface of the upper electrode filling layer 15 may be removed by a planarization process, wherein the upper electrode filling layer 15 may be formed as a stop layer during the planarization of the insulating layer 2, so that the upper electrode filling layer 15 is exposed after the insulating layer 2 on the top of the upper electrode filling layer 15 is removed.

Optionally, the planarization process may comprise a chemical mechanical polishing or coating and etching process. In some examples of the present disclosure, the insulating layer 2 on the upper surface of the upper electrode filling layer 15 may be removed by the chemical mechanical polishing process. For example, the insulating layer 2 on the upper surface of the upper electrode filling layer 15 may be polished and etched by chemical mechanical polishing equipment to expose the upper electrode filling layer 15 and remove the insulating layer 2 on the top of the upper electrode filling layer 15. In other examples of the present disclosure, the insulating layer on the upper surface of the upper electrode filling layer 15 may be removed by the coating and etching process. Specifically, a photoresist may be applied on the upper surface of the upper electrode filling layer 15 to perform planarization on the top of the insulating layer 2, and then the insulating layer 2 on the upper surface of the upper electrode filling layer 15 is etched until the stop layer is exposed. Further, gas etching at a lower etching rate may be adopted during etching.

In the step S3 of forming an upper electrode metal layer 16 on an upper surface of the upper electrode filling layer 15, specifically, an upper electrode metal layer 16 covering the upper surface of the upper electrode filling layer 15 may be deposited on the upper surface of the upper electrode filling layer 15. In the deposition process, a chemical vapor deposition method or a physical deposition method may be adopted.

Optionally, the step S3 may comprise following steps of: S301, depositing a metal layer on the upper surface of the upper electrode filling layer 15 and on an upper surface of the insulating layer 2 on the side face of the upper electrode filling layer 15, respectively; and S302, removing the metal layer on the upper surface of the insulating layer 2 on the side face of the upper electrode filling layer 15 and retaining the metal layer on the upper surface of the upper electrode filling layer 15 to form the upper electrode metal layer 16. Specifically, the insulating layer 2 is formed on the side face of the upper electrode filling layer 15, so that a metal layer is deposited on both the upper surface of the upper electrode filling layer 15 and the upper surface of the insulating layer 2 on the side face of the upper electrode filling layer 15 during the deposition of the upper electrode metal layer 16, and the upper electrode metal layer 16 is deposited on the upper electrode filling layer 15 by removing the metal layer on the upper surface of the insulating layer 2. Further, a reticle may be provided above the upper electrode metal layer 16 to remove the upper electrode metal layer 16 formed on the upper surface of the insulating layer 2 by etching.

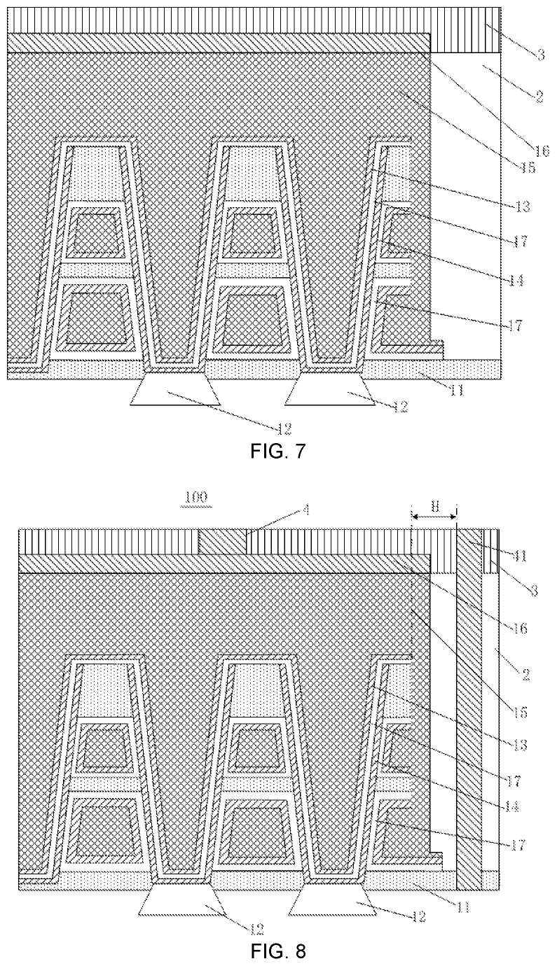

In the step S4 of forming a planarization layer 3 on an outer surface of the upper electrode metal layer 16, as shown in FIG. 7, the planarization layer 3 covering the upper surface of the insulating layer 2 is formed on an upper surface and a side face of the upper electrode metal layer 16, wherein the planarization layer 3 and the insulating layer 2 may be made of the same or different materials. In this embodiment, the planarization layer 3 and the insulating layer 2 are made of the same material comprising but not limited to silicon oxide, and cover the upper surface and the side face of the upper electrode metal layer 16 and the capacitor substrate 1. The planarization layer 3 may be formed by a deposition process, for example, by a chemical vapor process.

In the step S5, the first conductor 4 is formed above the upper electrode metal layer 16 and in the planarization layer 3 and connected to the upper electrode metal layer 16, and the second conductor 41 is formed on the side face of the upper electrode metal layer 16 and spaced from the upper electrode metal layer 16, and is connected to the lower circuit after running through the planarization layer 3, the insulating layer 2 and the isolation layer 1 in sequence. It should be noted that the lower circuit here refers to a circuit connected to bit lines, word lines, or circuits in a peripheral region. For example, the second conductor 41 may be connected to conductors in a peripheral region of the capacitor array structure, and may also be connected to bit lines and word lines after running through the isolation layer 1.

Specifically, a first through hole is formed in the planarization layer 3 to expose the upper electrode metal layer 16. The first through hole runs through the planarization layer 3 to expose the upper electrode metal layer 16, and is filled to form the first conductor 4. A second through hole running through the planarization layer 3, insulating layer 2 and isolation layer 11 is formed in the planarization layer 3, insulating layer 2 and isolation layer 11, and is filled to form the second conductor 41. Further, the first through hole and the second through hole may be formed by etching. Specifically, a reticle layer may be formed on the planarization layer 3 and patterned to expose regions where the first through hole and the second through hole are to be formed, and then the planarization layer 3, the insulating layer 2 and the isolation layer 1 are etched by taking the patterned reticle layer as a reticle to form the first through hole and the second through hole which are filled with materials to form the first conductor 4 and the second conductor 41. The first conductor 4 and the second conductor 41 may be made of metal materials such as tungsten, titanium and aluminum. During the formation of the first through hole and the second through hole, the first through hole and the second through hole may be formed simultaneously or in steps, which is not specifically defined herein.

According to the preparation method of the capacitor array structure in the embodiment of the present disclosure, the insulating layer 2 is formed on the side face of the upper electrode filling layer 15, and the upper electrode metal layer 16 is formed on the upper surface of the upper electrode filling layer 15, with no metal layer formed on the side face of the upper electrode filling layer 15, thereby not only avoiding the increased size of the capacitor array structure due to the formation of the metal layer on the side face of the upper electrode filling layer 15 and improving the integration level of the capacitor array structure, but also preventing the risk of leakage at a capacitor pin 18 and the second conductor 41.

In addition, the present disclosure further proposes a semiconductor memory device, comprising the capacitor array structure 100 in the above embodiments. According to the semiconductor memory device of the embodiment of the present disclosure, it is possible to improve the device integration level, improve the operation efficiency and reduce the risk of leakage by providing the capacitor array structure 100 in the above embodiments.

Those described above are merely preferred embodiments of the present disclosure. It should be noted that a number of improvements and refinements may be made by those of ordinary skill in the art without departing from the principles of the present disclosure, and such improvements and refinements shall also fall into the protection scope of the present disclosure.

What is claimed is:

1. A preparation method of a capacitor array structure, comprising:
providing a capacitor substrate, the capacitor substrate comprises an isolation layer, a lower electrode layer, capacitor dielectric layers, an upper electrode layer and an upper electrode filling layer, wherein the isolation layer is disposed on the substrate, the lower electrode layer is disposed above the isolation layer, the capacitor dielectric layers are disposed on inner and outer surfaces of the lower electrode, and the upper electrode layer is disposed on an outer surface of the capacitor dielectric layer and is filled and covered by the upper electrode filling layer;
forming an insulating layer on a side face of the upper electrode filling layer;
forming an upper electrode metal layer on an upper surface of the upper electrode filling layer;
forming a planarization layer on an outer surface of the upper electrode metal layer; and
forming a first conductor and forming a second conductor, the first conductor is connected to the upper electrode metal layer after running through the planarization layer, the second conductor is connected to a lower circuit after running through the planarization layer, the insulating layer and the isolation layer.

2. The preparation method of the capacitor array structure according to claim 1, wherein said forming an insulating layer on a side face of the upper electrode filling layer comprises:
forming an insulating layer on an outer surface of the upper electrode filling layer; and
removing the insulating layer on the upper surface of the upper electrode filling layer.

3. The preparation method of the capacitor array structure according to claim 2, wherein coating and etching processes are adopted in removing the insulating layer on the upper surface of the upper electrode filling layer.

4. The preparation method of the capacitor array structure according to claim 1, wherein forming an upper electrode metal layer on an upper surface of the upper electrode filling layer comprises:
depositing a metal layer on the upper surface of the upper electrode filling layer and on an upper surface of the insulating layer, respectively; and
removing the metal layer on the upper surface of the insulating layer and retaining the metal layer on the upper surface of the upper electrode filling layer to form the upper electrode metal layer.

5. The preparation method of the capacitor array structure according to claim 1, wherein in providing the capacitor substrate, the capacitor substrate is further configured to comprise a plurality of capacitor contact openings, the plurality of the capacitor contact openings are arranged at intervals, the plurality of the capacitor contact openings are formed below the isolation layer and connected to the lower electrode layer after running through the isolation layer.

6. The preparation method of the capacitor array structure according to claim 1, wherein the forming a first conductor and forming a second conductor, the first conductor is connected to the upper electrode metal layer after running through the planarization layer, the second conductor is connected to a lower circuit after running through the planarization layer, the insulating layer and the isolation layer, comprises:
forming a first through hole in the planarization layer to expose the upper electrode metal layer, filling the first through hole to form the first conductor, forming a second through hole running through the planarization layer, the insulating layer and the isolation layer, and filling the second through hole to form the second conductor.

7. A capacitor array structure, wherein the capacitor array structure is disposed on a semiconductor substrate and the capacitor array structure comprises:
a capacitor substrate, comprising an isolation layer, a lower electrode layer, capacitor dielectric layers, an upper electrode layer and an upper electrode filling layer, wherein a plurality of capacitor contact openings are disposed below the isolation layer, the lower electrode layer is disposed above the isolation layer and connected to the capacitor contact openings after running through the isolation layer, the capacitor dielectric layers are disposed on inner and outer surfaces of the lower electrode, and the upper electrode layer is formed on an outer surface of the capacitor dielectric layer and is filled and covered by the upper electrode filling layer;
an upper electrode metal layer, covering an upper surface of the upper electrode filling layer;
an insulating layer, formed on a side face of the upper electrode filling layer;
a planarization layer, formed on an outer surface of the upper electrode metal layer; and
a conductor, comprising a first conductor and a second conductor, wherein a first conductor is connected to the upper electrode metal layer after running through the planarization layer, and a second conductor is connected to a lower circuit after running through the planarization layer, the insulating layer and the isolation layer in sequence.

8. The capacitor array structure according to claim 7, wherein a thickness of the upper electrode metal layer is 80-120 nm.

9. The capacitor array structure according to claim 7, wherein a minimum distance between the second conductor and a top of the upper electrode layer is greater than or equal to 300 nm.

10. A semiconductor memory device, comprising the capacitor array structure according to claim 7.
